(19) United States
(12) Patent Application Publication
(10) Pub. No.: US 2025/0385649 A1
(43) Pub. Date: Dec. 18, 2025

(54) INDUCTIVELY COUPLED MULTI-STACK AMPLIFIER

(71) Applicant: QUALCOMM Incorporated, San Diego, CA (US)

(72) Inventors: Kai ZHAN, Escondido, CA (US); Chinmaya MISHRA, San Diego, CA (US); Chuan WANG, San Diego, CA (US)

(21) Appl. No.: 18/742,894

(22) Filed: Jun. 13, 2024

(51) Int. Cl. H03F 1/56; H03F 3/24

(52) U.S. Cl. CPC H03F 1/565; H03F 3/245; H03F 2200/451

(57) ABSTRACT

Certain aspects of the present disclosure provide an inductively coupled multi-stack amplifier. An example amplifier includes a first transistor stack comprising a first input node, a first transistor, and a second transistor. The amplifier further includes a second transistor stack comprising a second input node, a third transistor, and a fourth transistor, wherein the first input node and the second input node form an input pair for a differential input signal. The amplifier further includes a first inductive element having a first terminal coupled between the first transistor and the second transistor. The amplifier further includes a second inductive element having a second terminal coupled to a drain of the second transistor, wherein the first inductive element is arranged to be inductively coupled to the second inductive element.

### INTRODUCTION

### Filed of the Disclosure

Aspects of the present disclosure relate to amplifiers, and more particularly, to a multi-stack amplifier, such as of a radio frequency transceiver.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate RF signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a radio frequency (RF) transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still encounter certain distortions in a power amplifier. Accordingly, there is a continuous desire to improve the technical performance of RF circuitry, such as a power amplifier.

### SUMMARY

Some aspects provide an amplifier. The amplifier includes a first transistor stack comprising a first input node, a first transistor, and a second transistor. The amplifier further includes a second transistor stack comprising a second input node, a third transistor, and a fourth transistor, wherein the first input node and the second input node form an input pair for a differential input signal. The amplifier further includes a first inductive element having a first terminal coupled between the first transistor and the second transistor. The amplifier further includes a second inductive element having a second terminal coupled to a drain of the second transistor, wherein the first inductive element is arranged to be inductively coupled to the second inductive element.

Some aspects provide a radio frequency (RF) transceiver. The transceiver includes a transmit chain comprising an amplifier, wherein the amplifier comprises a first transistor stack comprising a first input node, a first transistor, and a second transistor; a second transistor stack comprising a second input node, a third transistor, and a fourth transistor, wherein the first input node and the second input node form an input pair for a differential input signal; a first inductive element having a first terminal coupled between the first transistor and the second transistor; and a second inductive element having a second terminal coupled to a drain of the second transistor, wherein the first inductive element is arranged to be inductively coupled to the second inductive element. The transceiver further includes one or more memories; and one or more processors coupled to the one or more memories and the transmit chain, the one or more processors being configured to provide a signal to the transmit chain for transmission.

Some aspects provide a method of operating an amplifier. The method includes outputting a first control signal that triggers a first set of switches to switch from a first mode to a second mode. The method includes amplifying a first differential input signal, via an amplifier, while the first set of switches is in the second mode. The amplifier comprises a first transistor stack comprising a first input node, a first transistor, and a second transistor; a second transistor stack comprising a second input node, a third transistor, and a fourth transistor, wherein the first input node and the second input node form an input pair for the first differential input signal; a first inductive element having a first terminal coupled between the first transistor and the second transistor; and a second inductive element having a second terminal coupled to a drain of the second transistor, wherein the first inductive element is arranged to be inductively coupled to the second inductive element.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications system.

FIG. 2 illustrates an example wireless communication device communicating with another device.

FIG. 3 depicts an example multi-stack amplifier with inductive coupling.

FIG. 4 depicts an example multi-stack amplifier with reconfigurable transistor stacks.

FIG. 5 depicts another example multi-stack amplifier with reconfigurable transistor stacks.

FIGS. 6A, 6B, and 7 depict example chip layouts for a multi-stack amplifier with inductive coupling.

FIG. 8 depicts the performance associated with a multi-stack amplifier operating in different transistor stack modes.

FIG. 9 illustrates example operations for wireless communications by an apparatus.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatus, methods, processing systems, and computer-readable mediums for a multi-stack amplifier with inductive coupling and/or dynamic transistor stack configuration. Certain aspects are discussed herein with respect to use of a multi-stack amplifier for wireless communications. However, it should be understood that the aspects of a multi-stack amplifier discussed herein may similarly be used for other suitable purposes.

In certain cases, an RF transmitter may use a power amplifier (PA) to amplify a signal for transmission via an antenna. For example, the PA may convert a low-power RF signal into a higher power RF signal, and the output of the power amplifier may drive the antenna to emit RF energy for wireless communications. The output of the PA may have certain harmonic distortions, including a second harmonic and/or a third harmonic, for example, due to non-linear characteristics associated with the PA and/or other circuitry (e.g., a mixer) in a transmit chain of the transmitter. The harmonic distortions may affect the performance of the PA, such as adjacent channel leakage ratio (ACLR), error vector magnitude (EVM), power output, etc. In certain cases, a power amplifier may employ a stack of transistors connected in series in order to increase the output power, efficiency, and bandwidth of the power amplifier. Such an amplifier may be referred to as a stacked-transistor amplifier or a multi-stack amplifier.

Technical problems for certain stacked-transistor amplifiers may include, for example, applying an effective harmonic trap to control certain harmonics in the amplifier output and/or enabling effective output power efficiency for a range of supply voltages and/or output powers. In certain aspects, intermediate nodes between transistors in a transistor stack of an amplifier may have a reactive component (e.g., a parasitic capacitance caused by transistor and/or interconnect capacitances) that can contribute to non-linear harmonic distortions, including amplitude-to-phase modulation (AM-PM) conversion and/or amplitude-to-amplitude modulation (AM-AM) conversion. The reactive component may also contribute to reduced stacking efficiency and/or the stability at the gates of common-gate amplifiers in the stack. These issues can be significant at millimeter-wave (mmWave) frequencies (e.g., 30 GHz to 300 GHz) and compound as more transistors are added to the transistor stack. In addition, as more transistors are added to the transistor stack to increase the peak output power of an amplifier, the performance of the amplifier at lower output powers may be affected by the additional transistors, such as EVM, ACLR, and/or output power efficiency.

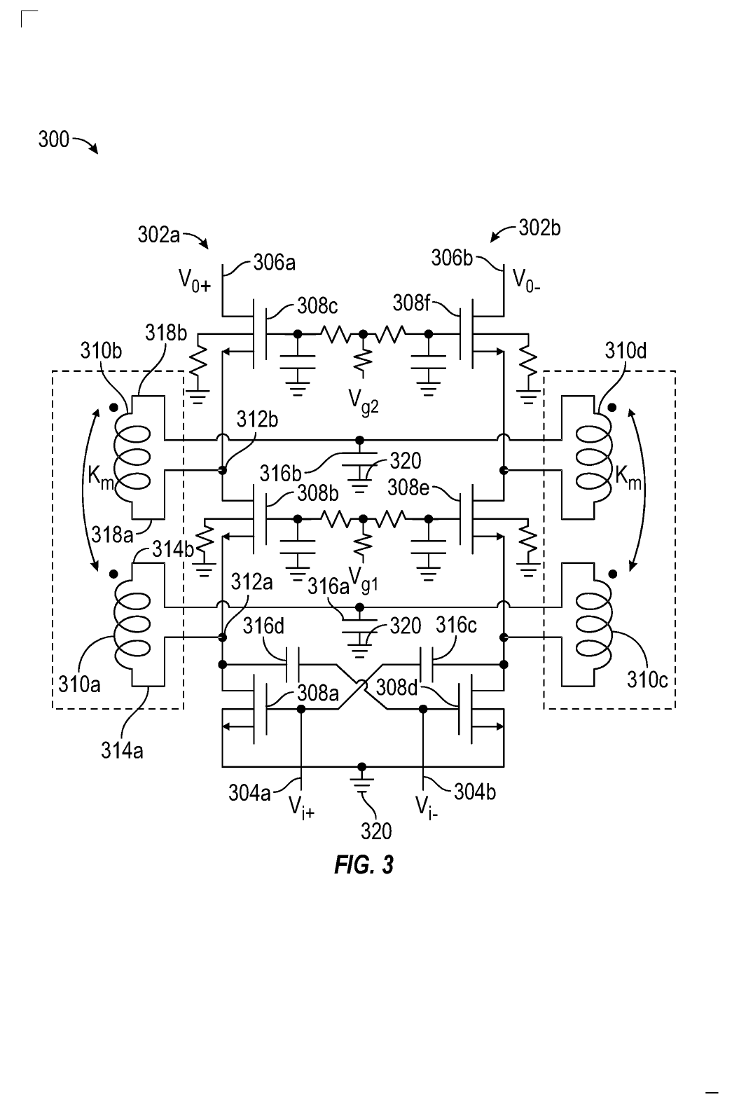

Aspects described herein may overcome the aforementioned technical problem(s) by providing a multi-stack amplifier that employs inductive coupling at certain nodes in a transistor stack in order to enhance the impedance matching at such nodes. For example, inductive elements (e.g., shunt inductors) may be coupled at intermediate nodes (e.g., a node between transistors) of the transistor stack to provide impedance matching at the intermediate nodes to compensate for the reactive components, and the inductive elements may be arranged to be inductively coupled with each other, as further described herein with respect to FIG. 3. The inductive coupling may enable at least one of the shunt inductors to resonate and trap certain harmonic distortions, such as a second harmonic. The inductive coupling between shunt inductors may provide an additional parameter (e.g., the coupling factor between inductors) for tuning the resonance of the harmonic trap.

In certain aspects, the multi-stack amplifier may include a set of switches arranged in parallel with transistors in the stack. The switches may enable selection of which transistors to enable or bypass in the stack to dynamically select the effective number of operational transistors in the stack. Therefore, the multi-stack amplifier may be reconfigurable into any of multiple transistor stack configurations, such as a two-stack amplifier, a three-stack amplifier, a four-stack amplifier, etc. The dynamic selection of the effective number of transistors enabled in a stack may enable reconfiguration of a multi-stack amplifier depending on an operational state of the amplifier (e.g., supply voltage and/or output power). For example, at a low supply voltage and low output power, the multi-stack amplifier may be reconfigured to operate as a two-stack amplifier, whereas at a high supply voltage and high output power, the multi-stack amplifier may be reconfigured to operate as a three-stack amplifier or four-stack amplifier.

Certain architecture(s) for a multi-stack amplifier described herein may provide various beneficial technical effects and/or advantages. The architecture(s) may enable improved amplifier performance, such as reduced ACLR, reduced EVM, and/or increased power-added efficiency (PAE). The improved amplifier performance may be attributable to the inductive coupling at intermediate nodes of a transistor stack to trap certain harmonic distortions, such as a second harmonic of a carrier frequency. In some cases, the improved amplifier performance may be attributable to the multi-stack amplifier that enables reconfiguration of the multi-stack amplifier depending on the operational state of the amplifier. For example, at a low supply voltage and low output power, the multi-stack amplifier may be reconfigured to operate as a two-stack amplifier with increased PAE than a three-stack or four-stack configuration, and at a higher supply voltage and a higher output power, the multi-stack amplifier may be reconfigured to operate as a three-stack amplifier or a four-stack amplifier with reduced EVM than a two-stack configuration.

### Example Wireless Communications System

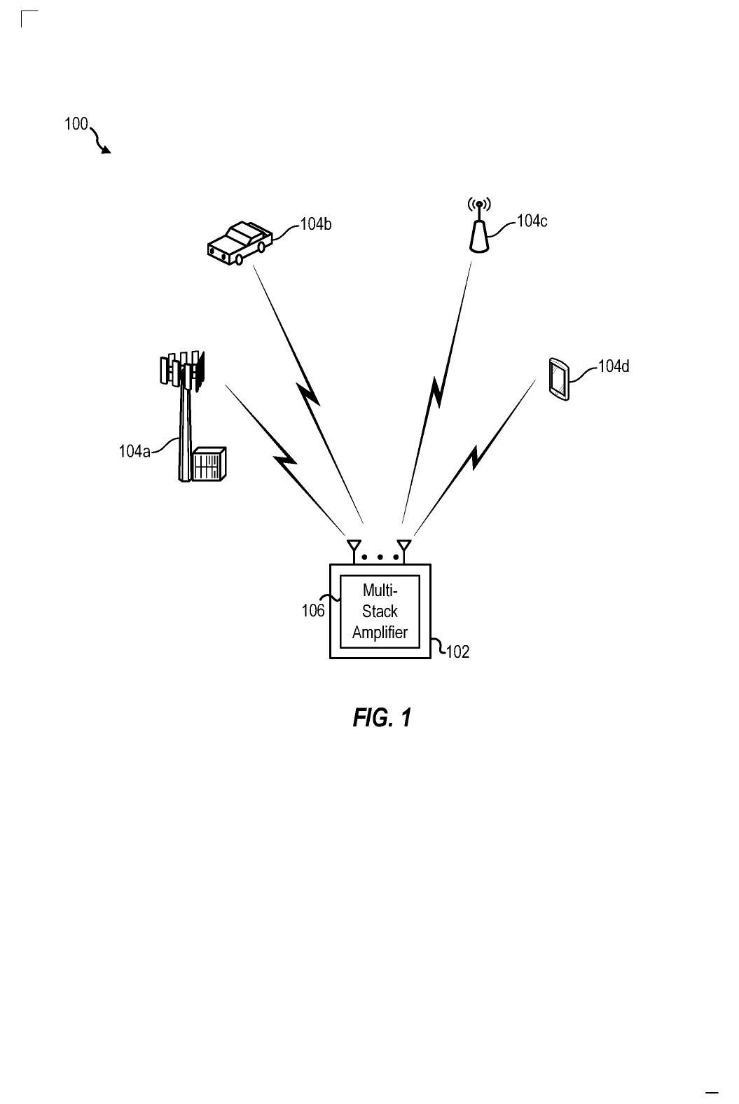

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), etc.

The first wireless device 102 may include any of various wireless communications devices including a user equipment (UE), a base station, a wireless station, an access point, customer-premises equipment (CPE), etc. In certain aspects, the first wireless device 102 includes a multi-stack amplifier 106 that employs inductive coupling to trap certain harmonic distortions and a set of switches to dynamically reconfigure a stack of transistors, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

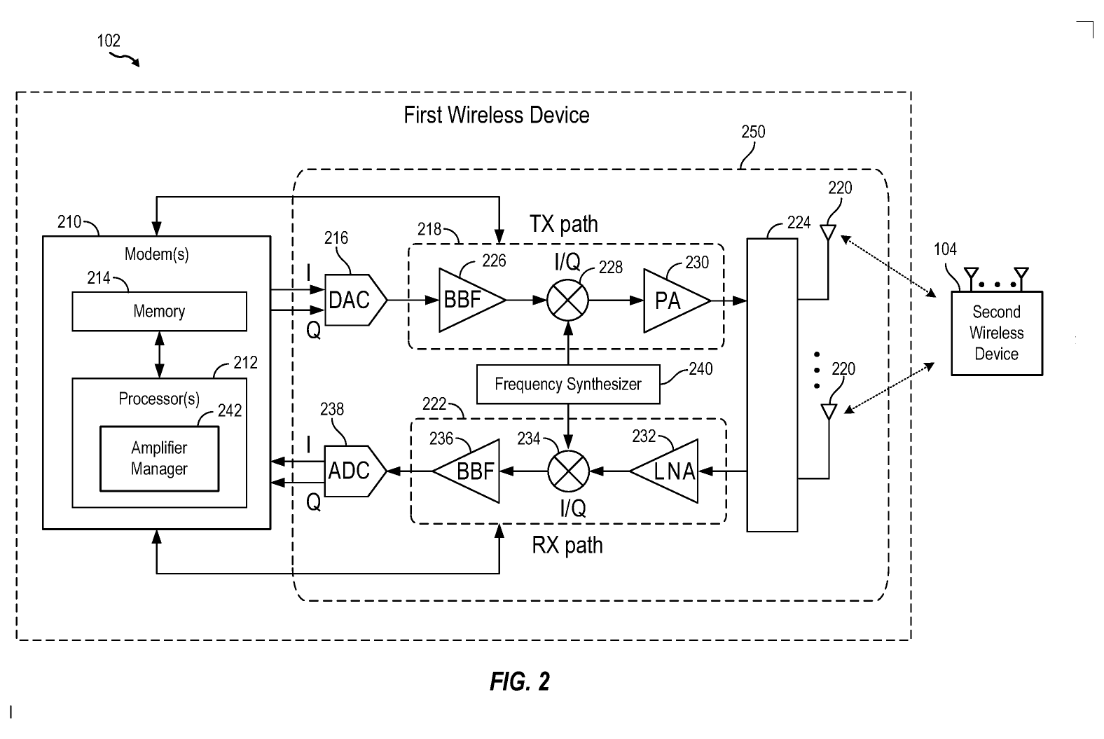

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In some cases, the processor 212 may implement and/or include an amplifier manager 242 that controls operational mode of a multi-stack amplifier, as further described herein. In certain aspects, the processor 212 and/or the memory 214 are implemented external or otherwise separate from the modem 210. For example, the processor 212 may be or include a controller or processor integrated with the RF transceiver 250 and/or external to and in communication with the RF transceiver 250.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a phase shifter, an antenna tuner, a switch, a duplexer, a diplexer, a multiplexer, and the like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof and/or a power amplifier (PA) 230 is also omitted from the single chip.

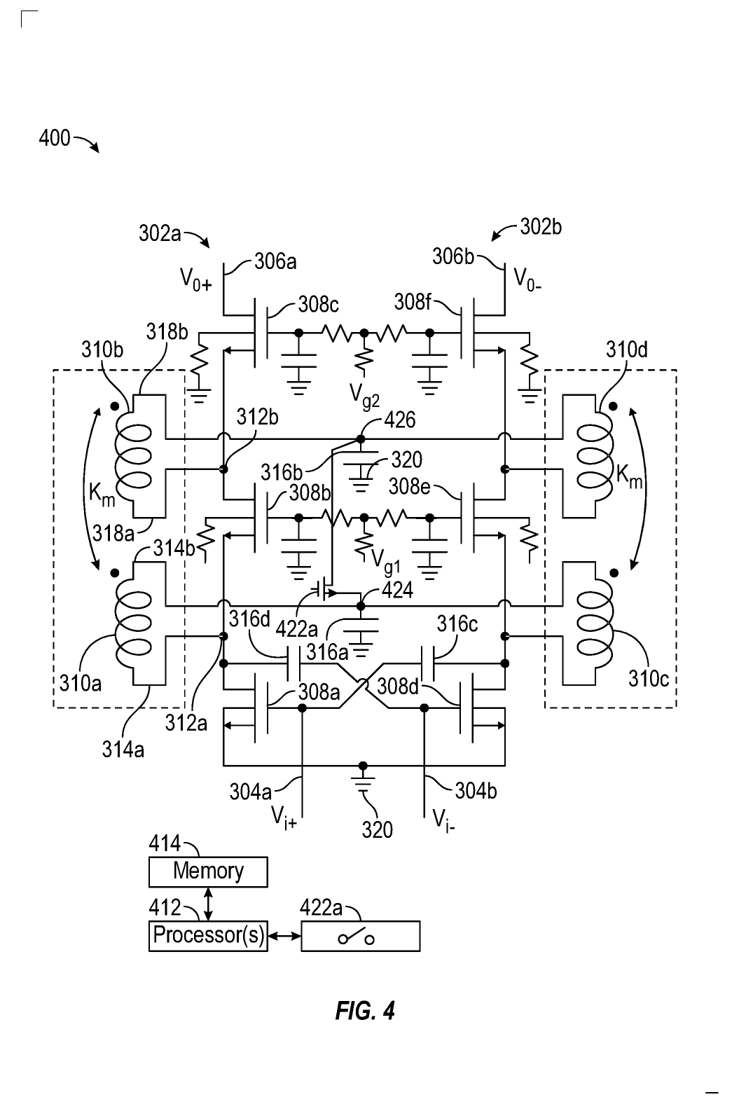

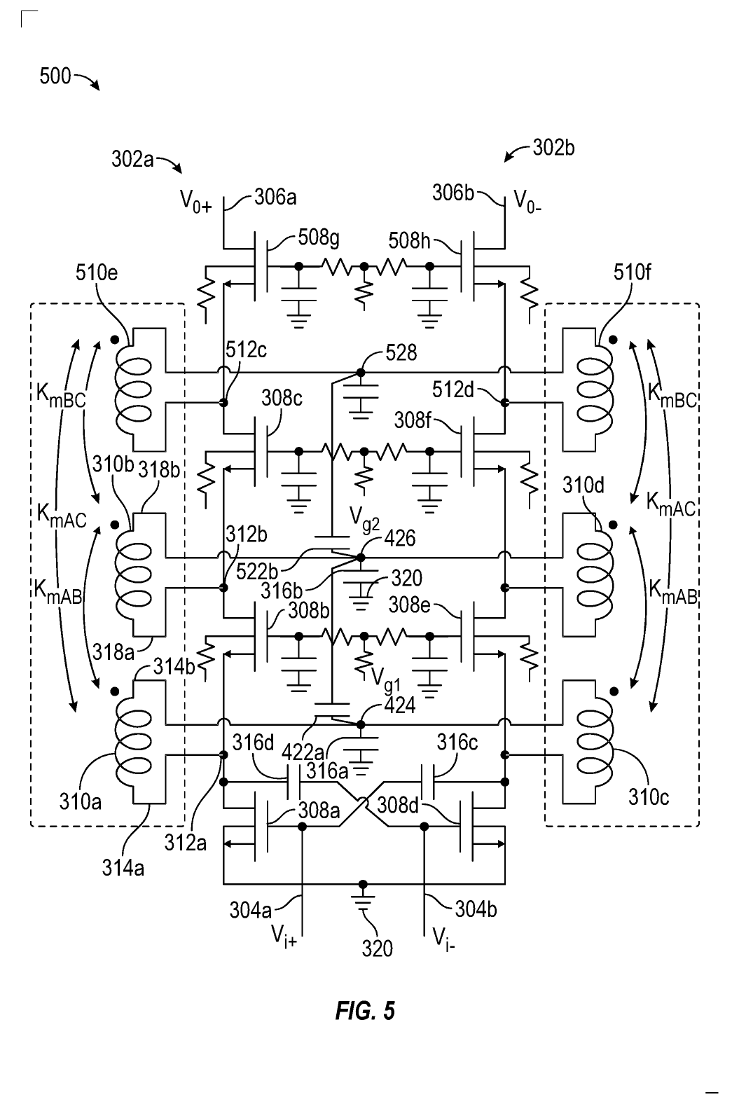

Receiving I or Q baseband analog signals from the DAC 216, the TX path 218 may include a baseband filter (BBF) 226, a mixer 228 (which may include one or several mixers), and the PA 230. The BBF 226 filters the baseband signals received from the DAC 216, and the mixer 227 mixes the filtered baseband signals with a transmit local oscillator (LO) signal to convert the baseband signal to a different frequency (e.g., upconvert from baseband to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The PA 230 may be or include a multi-stack amplifier, such as the multi-stack amplifier 106 of FIG. 1. The PA 230 may employ inductive coupling along a transistor stack to adjust the level of harmonic distortion in an RF output signal, for example, as further described herein with respect to FIG. 3. The PA 230 may have a reconfigurable transistor architecture to enable operation via a plurality of stack configurations, such as a two-stack amplifier, three-stack amplifier, four-stack amplifier, etc., for example, as further described herein with respect to FIGS. 4 and 5. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated or with the memory 214 being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Multi-Stack Amplifier

Aspects of the present disclosure provide apparatus and methods for a multi-stack amplifier with inductive coupling and/or dynamic transistor stack configuration. In certain cases, the multi-stack amplifier may be arranged in a transmit chain coupled to a phased antenna array. As an example, the multi-stack amplifier may be part of beamsteering circuitry, including a phase shifter, coupled to an antenna of a phased array, where multiple antennas may be arranged in an array to form the phased array to output a beamformed transmission. The multi-stack amplifier may be coupled to the phase shifter, such that the amplifier and phase shifter apply gain and phase to an RF signal for beamsteering, respectively.

FIG. 3 depicts an example multi-stack amplifier 300 with inductive coupling. In this example, the multi-stack amplifier 300 is a differential amplifier that includes a first transistor stack (hereinafter “the first stack 302a”) and a second transistor stack (hereinafter “the second stack 302b”). A differential input signal may be applied to an input pair formed via a first input node 304a of the first stack 302a and a second input node 304b of the second stack 302b; and a differential output signal may be formed across a differential output pair formed via a first output node 306a of the first stack 302a and a second output node 306b of the second stack 302b.

The first stack 302a may be or include a plurality of transistors. The transistors of the first stack may be arranged in a chain or sequence of N series-connected transistors (with N = 3 in the example depicted) in order to distribute the supply power (e.g., via biasing voltages applied to gates of the upper transistors in the first stack 302a) across multiple transistors. Upper transistor(s) may refer to any transistor that is arranged after the transistor (e.g., the input transistor) that is first in order of the chain of series-connected transistors. A series interconnection in the first stack 302a may be between a drain of a transistor and a source of the next transistor in the first stack 302a. As an example, the first stack 302a includes a first transistor 308a, a second transistor 308b, and a third transistor 308c. The drain of the first transistor 308a is coupled to the source of the second transistor 308b, and the drain of the second transistor 308b is coupled to the source of the third transistor 308c. An RF input signal (e.g., V i+) may be applied to the gate of the bottom transistor (e.g., the first transistor 308a) in the first stack 302a, and an output voltage (e.g., V o+) may be formed at the drain of the topmost transistor (e.g., the third transistor 308c) in the first stack 302a. The bottom transistor may refer to the transistor that is first in order of the chain of series-connected transistors (e.g., the input transistor), and the topmost transistor may refer to the transistor that is last in order of the chain of series-connected transistors (e.g., the output transistor). The first input node 304a may be coupled to the gate of the first transistor 308a, and the first output node 306a may be coupled to the drain of the third transistor 308c.

In certain aspects, load impedances presented at intermediate nodes of the first stack 302a may have a reactive component that can be significant at millimeter-wave frequencies, for example, due to capacitances of the series-connected transistors and interconnects between such transistors. Millimeter-wave frequencies may refer to a range of electromagnetic frequencies from 30 GHz to 300 GHz. In certain cases, millimeter-wave frequencies may include certain frequency bands of 5G New Radio systems, such as Frequency Range 2 including frequencies of 24.25 GHz to 71 GHz. The millimeter-wave frequencies may include the frequency bands of IEEE 802.11 systems, such as the 60 GHz bands of 802.11ad and/or 802.11ay. In some examples, a multi-stack amplifier as described herein is configured to amplify signals including such millimeter-wave frequencies. In other examples, a multi-stack amplifier as described herein is configured to amplify signals including lower frequencies or higher frequencies, for example in the sub-THz or THz range.

To compensate for the reactive component and provide impedance matching at the intermediate nodes, a shunt inductor connected via a DC blocking capacitor to a reference potential (e.g., a ground node) may be coupled at an intermediate node. For example, a first inductive element 310a is coupled to a first intermediate node 312a arranged between the first transistor 308a and the second transistor 308b. More specifically, a first terminal 314a of the first inductive element 310a is coupled between the drain of the first transistor 308a and the source of the second transistor 308b, and a second terminal 314b of the first inductive element 310a is coupled to a first capacitive element 316a. A second inductive element 310b may be coupled to a second intermediate node 312b arranged between the second transistor 308b and the third transistor 308c. More specifically, a first terminal 318a of the second inductive element 310b is coupled between the drain of the second transistor 308b and the source of the third transistor 308c, and a second terminal 318b of the second inductive element 310b is coupled to a second capacitive element 316b. The first capacitive element 316a is coupled between the second terminal 314b of the first inductive element 310a and a reference potential node 320 (e.g., a ground node). The second capacitive element 316b is coupled between the second terminal 318b of the second inductive element 310b and the reference potential node 320.

A gate voltage (e.g., a common-mode biasing voltage for a differential amplifier) may be applied to the gates of the upper transistors in the first stack 302a, such as the second transistor 308b and the third transistor 308c. In certain aspects, the gate voltages may be incremented going up the first stack. For example, a first gate voltage (V g1) is applied to the gate of the second transistor 308b, and a second gate voltage (V g2) is applied to the gate of the third transistor 308c, where the second gate voltage is greater than the first gate voltage.

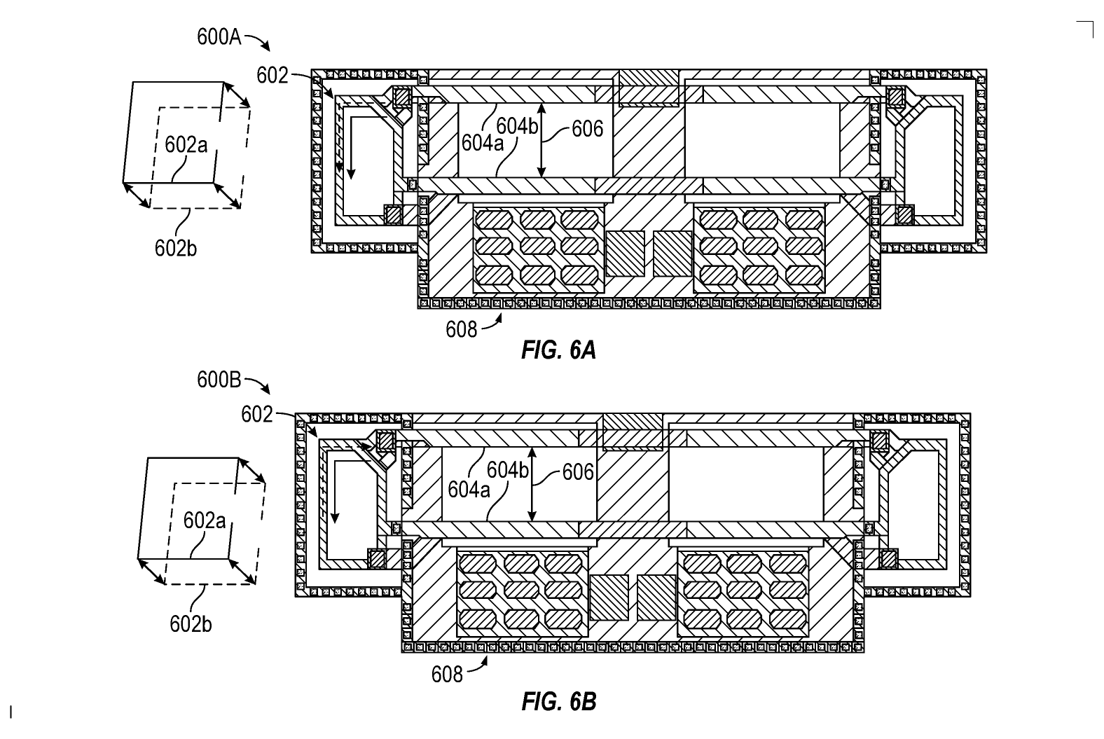

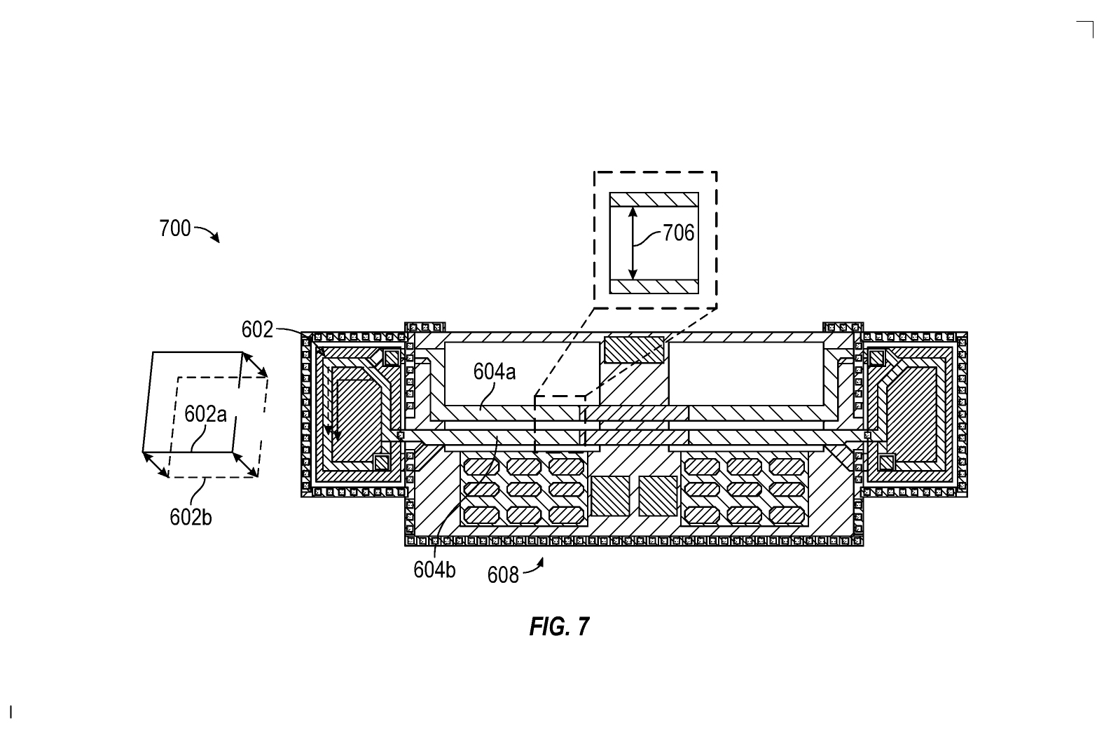

To improve the reactive component compensation discussed above and/or trap certain harmonic distortion(s) (e.g., attenuate and/or suppress a second harmonic distortion (HD2) of a carrier frequency in the RF input signal), the first inductive element 310a may be inductively coupled to the second inductive element 310b. As an example, the first inductive element 310a may be arranged above or below the second inductive element 310b in a chip or die to be inductively coupled to the second inductive element 310b, for example, as further described herein with respect to FIGS. 6A, 6B, and 7. The inductive coupling between the first inductive element 310a and the second inductive element 310b may allow certain harmonic distortion(s) present in the RF signal to be suppressed or attenuated. For example, the first inductive element 310a, the second inductive element 310b, the mutual inductance between the first inductive element 310a and the second inductive element 310b, the first capacitive element 316a, and/or the second capacitive element 316b may form a resonant circuit (e.g., an inductor-capacitor (LC) filter and/or an L-C-L filter) that is tuned to adjust (e.g., trap, attenuate, and/or suppress) a harmonic distortion. In certain aspects, the coupling factor between the first inductive element 310a and the second inductive element 310b may be used to tune the suppression of the harmonic distortion and/or the reactive component compensation.

The second stack 302b may be arranged as a chain of transistors with shunt inductor(s) coupled at each of the intermediate nodes of the second stack 302b as described herein with respect to the first stack 302a. For example, the second stack 302b may include a fourth transistor 308d, a fifth transistor 308e, and a sixth transistor 308f. An RF input signal (e.g., V i-) may be applied to the gate of the bottom transistor (e.g., the fourth transistor 308d) in the second stack 302b, and an output voltage (e.g., V o-) may be formed at the drain of the topmost transistor (e.g., the sixth transistor 308f) in the second stack 302b. The second input node 304b may be coupled to the gate of the fourth transistor 308d, and the second output node 306b may be coupled to the drain of the sixth transistor 308f. A third inductive element 310c is coupled between the fourth transistor 308d and the fifth transistor 308e, and a fourth inductive element 310d is coupled between the fifth transistor 308e and the sixth transistor 308f. The third inductive element 310c may be inductively coupled to the fourth inductive element 310d as described herein with respect to the inductive coupling associated with the first inductive element 310a and the second inductive element 310b.

The inductive coupling may enable shunt inductor tuning at the intermediate nodes of the first stack 302a and/or the second stack 302b. The inductive coupling may enable improved AM-PM conversion and/or AM-AM conversion for the multi-stack amplifier 300 by resonating out harmonic distortions caused by non-linear parasitic capacitances at the intermediate nodes. For example, the first inductive element 310a, second inductive element 310b, the first capacitive element 316a, and/or the second capacitive element 316b may effectively function as a common-mode second harmonic distortion trap. The inductive coupling enables an improved load line for the transistors of the first stack 302a and the second stack 302b, and thus, the stacking efficiency (e.g., output gain per stacked transistor) of the first stack 302a and/or the second stack 302b can be improved. The inductive coupling enables suppression of capacitive source degeneration for the upper transistors (e.g., the common-gate amplifier transistor topologies) in the first stack 302a and/or the second stack 302b at the intermediate nodes, and thus, the inductive coupling enables reactive component compensation discussed above.

In certain aspects, the first input node 304a may be cross-coupled, via a third capacitive element 316c, with the drain of the fourth transistor 308d of the second stack 302b; and the second input node 304b may be cross-coupled, via a fourth capacitive element 316d, with the drain of the first transistor 308a of the first stack 302a. The cross-coupled inputs may enable tuning for the input impedance of the multi-stack amplifier 300. The cross-coupled inputs may distribute the input signals across the first transistor 308a, the second transistor 308b, the fourth transistor 308d, and the fifth transistor 308e.

Any of the transistors 308a-f may be or include a field effect transistor (FET) including, for example, a silicon-based FET and/or silicon-on-insulator (SOI) FET. Any of the inductive elements 310a-d may be or include an inductor, such as an RF coil inductor formed via a coiled conductive trace as further described herein with respect to FIG. 6A or a spiral inductor. Any of the capacitive elements 316a-d may be or include a tantalum capacitor, aluminum capacitor, ceramic capacitor, varactor, a metal-insulator-metal (MIM) capacitor, metal-oxide-metal (MOM) capacitor, a metal-oxide-semiconductor (MOS) capacitor, a metal fringe capacitor, a trench capacitor, a junction capacitance of a diode or transistor, or the like.

In certain aspects, a multi-stack amplifier may be reconfigurable in terms of the total number transistors that are effectively stacked in a transistor stack. Stack reconfiguration may enable the multi-stack amplifier to be operated in various power modes with differing performance characteristics. For example, in a low power mode when the output power of the multi-stack amplifier is relatively low (e.g., less than or equal to 20 dBm), the multi-stack amplifier may be reconfigured to operate with a subset of transistors in the transistor stack. As a subset of transistors are activated, the multi-stack amplifier can operate at a lower supply voltage and reduce power consumption. In a high power mode when the output power is expected to be relatively high (e.g., greater than 20 dBm), the multi-stack amplifier may be reconfigured to operate with more transistors than a low power mode. In the high power mode, the multi-stack amplifier can achieve a higher saturation point resulting in an improved EVM for the higher output powers.

FIG. 4 depicts an example multi-stack amplifier 400 with dynamic stack configuration. In this example, the multi-stack amplifier may be arranged as described herein with respect to the multi-stack amplifier 300, except as described below.

The multi-stack amplifier 400 may include a first switch 422a coupled in parallel with the second transistor 308b and the fifth transistor 308e. The first switch 422a may be or include a transistor, such as a FET. The first switch 422a may be configured to selectively bypass or enable the second transistor 308b and the fifth transistor 308e. More specifically, a first node 424 is coupled (or arranged) between the second terminal 314b of the first inductive element 310a and the first capacitive element 316a, and the first node 424 is arranged between the third inductive element 310c and the first capacitive element 316a. A second node 426 is coupled (or arranged) between the second terminal 318b of the second inductive element 310b and the second capacitive element 316b, and likewise the second node 426 is arranged between the fourth inductive element 310d and the second capacitive element 316b. The first switch 422a may be coupled between the first node 424 and the second node 426.

The first switch 422a may be configured to switch between a first mode and a second mode. In the first mode, the first switch 422a may be closed, and the second transistor 308b and the fifth transistor 308e may be bypassed in the first stack 302a and the second stack 302b, respectively. Thus, in the first mode, the multi-stack amplifier 400 effectively operates as a two-stack amplifier, for example, to achieve efficient amplification at low output powers (e.g., in terms of PAE, EVM, and/or ACLR) and/or low supply voltages. In the second mode, the first switch 422a may be open, and the second transistor 308b and the fifth transistor 308e may be enabled in the first stack 302a and the second stack 302b, respectively, and the multi-stack amplifier 400 operates as a three-stack amplifier, for example, to achieve efficient amplification at higher output powers (e.g., in terms of PAE, EVM, and/or ACLR) and/or higher supply voltages.

In certain aspects, a processor 412 may be coupled to the first switch 422a to control when the first switch 422a is switched between the first mode or the second mode. For example, the processor 412 may output a first control signal to trigger the first switch 422a to switch from the first mode to the second mode, and the processor 412 may output a second control signal to trigger the first switch 422a to switch from the second mode to the first mode. The processor 412 may be coupled to and in communication with memory 414. The processor 412 may be an example of the processor 212 described herein with respect to FIG. 2, and the memory 414 may be an example of the memory 214 described herein with respect to FIG. 2. In certain aspects, an RF transceiver (e.g., the RF transceiver 250) may include the processor 412 and/or the memory 414.

FIG. 5 depicts an example multi-stack amplifier 500 that is configurable as a four-stack amplifier. In this example, the multi-stack amplifier 500 may be arranged as described herein with respect to the multi-stack amplifier 300 with additional transistors in the first stack 302a and the second stack 302b to form a four-stack amplifier. For example, the first stack 302a further includes a seventh transistor 508g, and the second stack 302b further includes an eighth transistor 508h. The first output node 306a and the second output node 306b may be coupled to (or arranged at) the drains of the seventh transistor 508g and the eighth transistor 508h, respectively.

In some cases, a fifth inductive element 510e may be coupled to an intermediate node 512c arranged between the third transistor 308c and the seventh transistor 508g of the first stack 302a, and a sixth inductive element 510f may be coupled to an intermediate node 512d arranged between the sixth transistor 308f and the eighth transistor 508h, for example, as described herein with respect to FIG. 3. The fifth inductive element 510e may be arranged to be inductively coupled to the first inductive element 310a and/or the second inductive element 310b. The sixth inductive element 510f may be arranged to be inductively coupled to the third inductive element 310c and/or the fourth inductive element 310d. Accordingly, in some cases, an inductive element may be inductively coupled to multiple other inductive elements coupled along a transistor stack.

The multi-stack amplifier 500 may include a set of switches, for example, including the first switch 422a and a second switch 522b. Each switch of the set of switches is arranged in parallel with at least one transistor of a set of upper transistors (e.g., the second transistor 308b, the third transistor 308c, the fifth transistor 308e, and the sixth transistor 308f) in the first stack 302a and the second stack 302b, for example, as described herein with respect to FIG. 4. Note that each switch of the set of switches is depicted as a capacitor in order to illustrate the effective capacitance present at a switch when the switch is open to enable a transistor in the first stack 302a and the second stack 302b. Accordingly, FIG. 5 depicts the multi-stack amplifier 500 operating as a four-stack amplifier, for example, for a high power mode.

With the set of switches, the multi-stack amplifier 500 is configurable as a two-stack amplifier, a three stack amplifier, and/or a four-stack amplifier, for example, depending on the output power expected or used for a transmission, supply voltage used for driving the multi-stack amplifier, and/or certain performance characteristics(s) expected for the operation of the multi-stack amplifier 500. The set of switches may be configured to switch among a plurality of modes, for example, including at least a first mode and a second mode. The first mode may be configured to bypass a first set of transistors (e.g., the second transistor 308b, the third transistor 308c, the fifth transistor 308e, and/or the sixth transistor 308f) in the first stack 302a and the second stack 302b. For example, in the first mode, the multi-stack amplifier 500 may be configured to operate as a two-stack amplifier. In certain aspects, the multi-stack amplifier 500 is configured to operate with a first supply voltage and a first output power while the set of switches is switched in the first mode.

The second mode may be configured to enable the first set of transistors in the first stack 302a and the second stack 302b. For example, in the second mode, the multi-stack amplifier 500 may be configured to operate as a four-stack amplifier. The multi-stack amplifier 500 may be configured to operate with a second supply voltage and a second output power while the first set of switches is switched in the second mode. The second supply voltage (e.g., Vdd = 2.5 Volts) may be higher than the first supply voltage (e.g., Vdd = 1.5 Volts), and the second output power (e.g., 20 dBm) may be higher than the first output power (e.g., 15 dBm). In addition, certain performance metrics may be achieved depending the expected output power. For example, as a two-stack amplifier in the first mode, the multi-stack amplifier may present improved EVM, PAE, and/or ACLR for low output powers; whereas as a three-stack amplifier and/or four-stack amplifier in the second mode or other mode(s), the multi-stack amplifier may present improved EVM, PAE, and/or ACLR for medium or high output powers.

In some cases, the set of switches may be configured to switch to a third mode, for example, where the first switch 422a is closed, and the second switch 522b is open, or vice versa. In certain aspects, in the third mode, the second transistor 308b and the fifth transistor 308e may be bypassed, and the third transistor 308c and the sixth transistor 308f may be enabled in the multi-stack amplifier 500. Thus, in the third mode, the multi-stack amplifier 500 may be configured to operate as a three-stack amplifier, for example, depending on the output power, supply voltage, and/or expected performance of the multi-stack amplifier 500. In other examples, the first node 424 may be coupled to a third node 528 by one or more switches without also being coupled to the second node 426.

Accordingly, the multi-stack amplifier 500 may be configurable to operate in a plurality of transistor stack configurations. A particular stack configuration may be selected based on the output power expected for a transmission and/or one or more expected performance metrics, e.g., EVM, PAE, and/or ACLR. For example, at low output powers (e.g., < 15 dBm), the multi-stack amplifier may be configured to operate as a two-stack amplifier. At medium output powers (e.g., 15 – 20 dBm), the multi-stack amplifier may be configured to operate as a three-stack amplifier. At high output powers (e.g., > 20 dBm), the multi-stack amplifier may be configured to operation as a four-stack amplifier.

Note that the transistor stacks described herein with respect to FIGS. 3-5 employ n-channel FETs to facilitate an understanding of multi-stack amplifiers. Aspects of the present disclosure may also apply to transistor stacks that comprise p-channel FETs. Further, while stacks having three or four transistors are illustrated, a multi-stack amplifier including a greater number of stacked transistors, and optionally a greater number of bypass paths/switches, may be implemented.

FIGS. 6A, 6B, and 7 depict example chip layouts 600A, 600B, and 700 for a multi-stack amplifier with certain inductive elements arranged to be inductively coupled with each other, such as the multi-stack amplifier 300, 400, 500. In these examples, inductive elements 602 (including a first inductive element 602a and a second inductive element 602b) are arranged to be inductively coupled with each other. The first inductive element 602a is arranged above the second inductive element 602b to enable inductive coupling between the first inductive element 602a and the second inductive element 602b. For example, the first inductive element 602a may be arranged at or in a first layer of a chip, and the second inductive element 602b may be arranged at or in a second layer below the first layer of the chip. The layered arrangement of the inductive elements 602 is shown with respect to an isometric view of the inductive elements 602. Each of the first inductive element 602a and the second inductive element 602b may be formed via a conductive loop or coil, for example. The inductive elements 602 may have the same shape or different shapes. The inductive elements 602 may be arranged adjacent to and electrically coupled to an amplifier core 608, which may include a transistor stack, for example, as described herein with respect to FIGS. 3-5.

The coupling coefficient (k) for the inductive coupling between the first inductive element 602a and the second inductive element 602b may be tuned based at least in part on a spacing arranged between a first conductive trace 604a and a second conductive trace 604b. The first conductive trace 604a is coupled to the first inductive element 602a, and the second conductive trace 604b is coupled to the second inductive element 602b. The first conductive trace 604a and the second conductive trace 604b may couple the first inductive element 602a and the second inductive element 602b, respectively, to an intermediate node of the transistor stack, for example, as described herein with respect to FIG. 3. In certain aspects, the coupling coefficient may be tuned based on the direction of the electrical current that flows through the first inductive element 602a and the second inductive element 602b, respectively. The coupling coefficient may adjust (e.g., suppress or attenuate) the level of certain harmonic distortions (e.g., the second harmonic distortion) present in the RF output signal as discussed above.

With respect to FIG. 6A, a first spacing 606 may be arranged between the first conductive trace 604a and second conductive trace 604b coupled to the first inductive element 602a and the second inductive element 602b, respectively. The current flowing through the first inductive element 602a and the second inductive element 602b may be flowing in the same direction (e.g., a counter clockwise direction as shown). Thus, the coupling coefficient may have a first value (e.g., k=0.16).

Referring to FIG. 6B, the first spacing 606 may be used between the first conductive trace 604a and the second conductive trace 604b. The current flowing through the first inductive element 602a and the second inductive element 602b may be flowing in opposite directions (e.g., clockwise and counter clockwise directions). Thus, the coupling coefficient may have a second value (e.g., k=0.07) lower than the first value.

As shown in FIG. 7, a second spacing 706 may be arranged between the first conductive trace 604a and the second conductive trace 604b, where the first spacing 606 is greater than the second spacing 706. The current flowing through the first inductive element 602a and the second inductive element 602b may be flowing in the same directions (e.g., a counter clockwise direction as shown). The coupling coefficient may have a third value (e.g., k=0.31) greater than the first value.

Due to the low coupling coefficient, the second chip layout 600B may provide better (e.g., lower) AM-PM conversion at certain output powers compared to the other chip layouts 600A, 700. Due to the high coupling coefficient, the chip layout 700 may provide better (e.g., lower) AM-AM conversion at certain output powers compared to the other chip layouts 600A, 600B. Thus, the arrangement of the inductive elements (and/or conductive traces) and/or the direction of current flowing through such elements may be designed to adjust the coupling coefficient (and/or mutual inductance), and in turn, the performance of the multi-stack amplifier. An amount of overlap of the inductive elements, and other factors, may also affect and/or be used to adjust the coupling coefficient and the performance of the multi-stack amplifier.

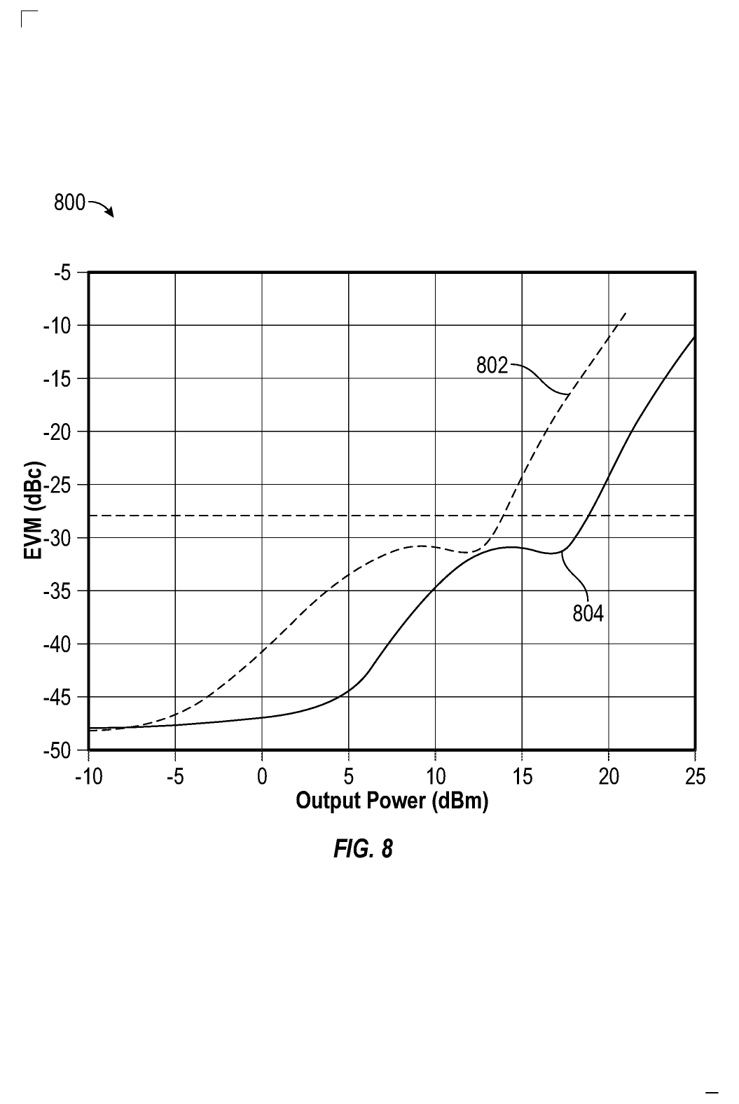

FIG. 8 depicts a graph 800 of EVM over output power associated with a multi-stack amplifier configured to operate in a two-stack mode and a three-stack mode. In this example, a first curve 802 is the EVM performance of the multi-stack amplifier when configured to operate as a two-stack amplifier with a supply voltage at a first voltage level. A second curve 804 is the EVM performance of the multi-stack amplifier when configured to operate as a three-stack amplifier with a supply voltage at a second voltage level higher than the first voltage level. The three-stack mode provides better EVM performance at higher output powers compared to the two-stack mode. Thus, the EVM performance depicted in FIG. 8 demonstrates that the two-stack mode can be used for low output powers, and the three-stack mode can be used for higher output powers while achieving the same level of EVM as the two-stack mode. Note that the EVM performance is an example of the selective performance among the plurality of stack configurations for a multi-stack amplifier described herein. For example, a particular transistor stack configuration may be selected to achieve a certain EVM, PAE, ACLR, AM-PM conversion, and/or AM-AM conversion for an expected output power and/or supply voltage.

Note that the differential amplifier configurations for multi-stack amplifiers depicted in FIGS. 3-5 are examples to facilitate an understanding of the inductive coupling and/or dynamic transistor stack configuration for a multi-stack amplifier. Aspects of the present disclosure may also be applied to a single-ended amplifier configuration.

Note that two-stack, three-stack, and four-stack configurations depicted in FIGS. 3-5 are examples to facilitate an understanding of a multi-stack amplifier. Aspects of the present disclosure may also be applied to any number of transistors arranged in a stack as described herein.

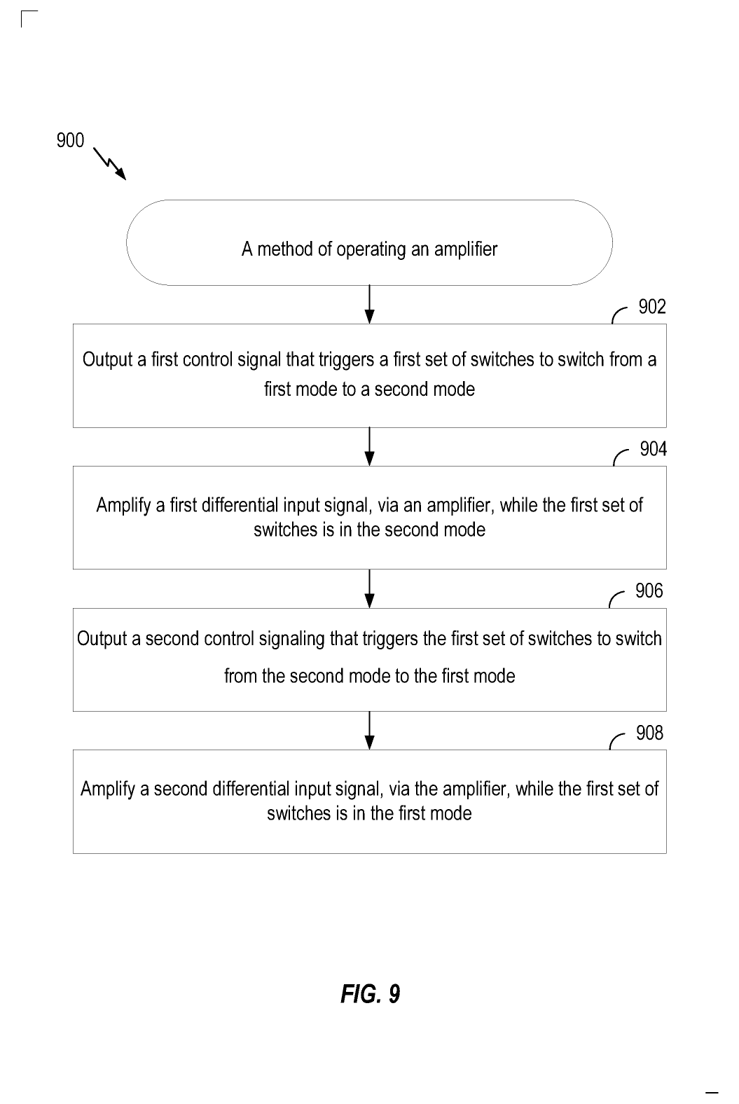

FIG. 9 illustrates example operations 900 for operating an amplifier. The operations 900 may be performed, for example, by a wireless device (e.g., the first wireless device 102 in the wireless communications system 100) and/or an RF transceiver (e.g., the RF transceiver 250). The operations 900 may be implemented as software components that are executed and run on one or more processors (e.g., the modem 210 and/or the processor 212 of FIG. 2). Further, the transmission and/or reception of signals by the wireless device in the operations 900 may be enabled, for example, by one or more antennas (e.g., the antennas 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission.

The operations 900 may optionally begin, at block 902, where the RF transceiver may output a first control signal that triggers a first set of switches to switch from a first mode to a second mode.

At block 904, the RF transceiver may amplify a first differential input signal, via an amplifier, while the first set of switches is in the second mode. The amplifier comprises: a first transistor stack comprising a first input node, a first transistor, and a second transistor; a second transistor stack comprising a second input node, a third transistor, and a fourth transistor, wherein the first input node and the second input node form an input pair for the first differential input signal; a first inductive element having a first terminal coupled between the first transistor and the second transistor; and a second inductive element having a second terminal coupled to a drain of the second transistor, wherein the first inductive element is arranged to be inductively coupled to the second inductive element. To amplify the first differential input signal, the RF transceiver may bypass a first set of transistors in the first transistor stack and the second transistor stack via the first set of switches, and the RF transceiver may operate the amplifier with a first supply voltage and a first output power while the first set of switches is switched in the second mode.

At block 906, the RF transceiver may output a second control signaling that triggers the first set of switches to switch from the second mode to the first mode.

At block 908, the RF transceiver may amplify a second differential input signal, via the amplifier, while the first set of switches is in the first mode. To amplify the second differential input signal, the RF transceiver may enable the first set of transistors in the first transistor stack and the second transistor stack, and the RF transceiver may operate the amplifier with a second supply voltage and a second output power while the first set of switches is switched in the first mode. The second supply voltage is higher than the first supply voltage, and the second output power is higher than the first output power.

Aspects of the present disclosure may be applied to any of various wireless communication devices that may transmit RF signals via a multi-stack amplifier with inductive coupling and/or dynamic stack configuration described herein.

Various components of a communications device (e..g, the first wireless communications device 102) may provide means for performing the operations 900 described with respect to FIG. 9, or any aspect related to operations described herein. Means for outputting may include, for example, the processor 212 and/or the processor 412. Means for amplifying may include the multi-stack amplifier 300, 400, 500.

### Example Aspects

Implementation examples are described in the following numbered clauses:

Aspect 1: An amplifier, comprising: a first transistor stack comprising a first input node, a first transistor, and a second transistor; a second transistor stack comprising a second input node, a third transistor, and a fourth transistor, wherein the first input node and the second input node form an input pair for a differential input signal; a first inductive element having a first terminal coupled between the first transistor and the second transistor; and a second inductive element having a second terminal coupled to a drain of the second transistor, wherein the first inductive element is arranged to be inductively coupled to the second inductive element.

Aspect 2: The amplifier of Aspect 1, further comprising: a third inductive element having a third terminal coupled between the third transistor and the fourth transistor; and a fourth inductive element having a fourth terminal coupled to a drain of the fourth transistor, wherein the third inductive element is arranged to be inductively coupled to the fourth inductive element.

Aspect 3: The amplifier of Aspect 2, wherein: the first transistor stack further comprises a fifth transistor; the second transistor stack further comprises a sixth transistor; the second terminal of the second inductive element is coupled between the second transistor and the fifth transistor; and the fourth terminal of the fourth inductive element is coupled between the fourth transistor and the sixth transistor.

Aspect 4: The amplifier of Aspect 3, further comprising a fifth inductive element having a fifth terminal coupled to a drain of the fifth transistor, wherein the fifth inductive element is arranged to be inductively coupled to the third inductive element and the first inductive element.

Aspect 5: The amplifier of Aspect 4, further comprising a sixth inductive element having a sixth terminal coupled to a drain of the sixth transistor, wherein the sixth inductive element is arranged to be inductively coupled to the third inductive element and the fourth inductive element.

Aspect 6: The amplifier according to any of Aspects 2–5, further comprising: a first capacitive element coupled between a fifth terminal of the first inductive element and a reference potential node and between a sixth terminal of the third inductive element and the reference potential node; and a second capacitive element coupled between a seventh terminal of the second inductive element and the reference potential node and between a eighth terminal of the fourth inductive element, wherein: the first inductive element, the first capacitive element, and the third inductive element form a first resonant circuit tuned to adjust a harmonic distortion; and the second inductive element, the second capacitive element, and the fourth inductive element form a second resonant circuit tuned to adjust the harmonic distortion.

Aspect 7: The amplifier according to any of Aspects 1–6, further comprising: a first capacitive element coupled between a third terminal of the first inductive element and a reference potential node; and a second capacitive element coupled between a fourth terminal of the second inductive element and the reference potential node, wherein: the first inductive element and the first capacitive element form a first resonant circuit tuned to adjust a harmonic distortion; and the second inductive element and the second capacitive element form a second resonant circuit tuned to adjust the harmonic distortion.

Aspect 8: The amplifier of Aspect 6 or 7, further comprising: a first node coupled between the third terminal of the first inductive element and the first capacitive element; a second node coupled between the fourth terminal of the second inductive element and the second capacitive element; and a switch coupled between the first node and the second node, wherein the switch is configured to selectively bypass or enable the second transistor.

Aspect 9: The amplifier according to any of Aspects 1–8, further comprising a set of switches, wherein at least one switch of the set of switches is coupled in parallel with the second transistor and the fourth transistor, wherein the set of switches is configured to switch among at least a first mode and a second mode, wherein the first mode is configured to bypass a set of transistors in the first transistor stack and the second transistor stack, and wherein the amplifier is configured to operate with a first supply voltage and a first output power while the set of switches is switched in the first mode.

Aspect 10: The amplifier of Aspect 9, wherein the second mode is configured to enable the set of transistors in the first transistor stack and the second transistor stack, wherein the amplifier is configured to operate with a second supply voltage and a second output power while the set of switches is switched in the second mode, wherein the second supply voltage is higher than the first supply voltage, and the second output power is higher than the first output power.

Aspect 11: The amplifier according to any of Aspects 1–10, wherein: the first input node is coupled to a gate of the first transistor; the second input node is coupled to a gate of the second transistor; the amplifier further comprises a first output node and a second output node, wherein the first output node and the second output node form a differential output pair for a differential output signal; the first output node is coupled to a first drain of the first transistor stack; and the second output node is coupled to a second drain of the second transistor stack.

Aspect 12: A radio frequency (RF) transceiver, comprising: a transmit chain comprising an amplifier, wherein the amplifier comprises: a first transistor stack comprising a first input node, a first transistor, and a second transistor; a second transistor stack comprising a second input node, a third transistor, and a fourth transistor, wherein the first input node and the second input node form an input pair for a differential input signal; a first inductive element having a first terminal coupled between the first transistor and the second transistor; and a second inductive element having a second terminal coupled to a drain of the second transistor, wherein the first inductive element is arranged to be inductively coupled to the second inductive element; one or more memories; and one or more processors coupled to the one or more memories and the transmit chain, the one or more processors being configured to provide a signal to the transmit chain for transmission.

Aspect 13: The RF transceiver of Aspect 12, wherein the amplifier further comprises: a third inductive element having a third terminal coupled between the third transistor and the fourth transistor; and a fourth inductive element having a fourth terminal coupled to a drain of the fourth transistor, wherein the third inductive element is arranged to be inductively coupled to the fourth inductive element.

Aspect 14: The RF transceiver of Aspect 13, wherein: the first transistor stack further comprises a fifth transistor; the second transistor stack further comprises a sixth transistor; the second terminal of the second inductive element is coupled between the second transistor and the fifth transistor; and the fourth terminal of the fourth inductive element is coupled between the fourth transistor and the sixth transistor.

Aspect 15: The RF transceiver of Aspect 14, wherein the amplifier further comprises a fifth inductive element having a fifth terminal coupled to a drain of the fifth transistor, wherein the fifth inductive element is arranged to be inductively coupled to the third inductive element and the first inductive element.

Aspect 16: The RF transceiver of Aspect 15, wherein the amplifier further comprises a sixth inductive element having a sixth terminal coupled to a drain of the sixth transistor, wherein the sixth inductive element is arranged to be inductively coupled to the third inductive element and the fourth inductive element.

Aspect 17: The RF transceiver according to any of Aspects 13–16, wherein the amplifier further comprises: a first capacitive element coupled between a fifth terminal of the first inductive element and a reference potential node and between a sixth terminal of the third inductive element and the reference potential node; and a second capacitive element coupled between a seventh terminal of the second inductive element and the reference potential node and between a eighth terminal of the fourth inductive element, wherein: the first inductive element, the first capacitive element, and the third inductive element form a first resonant circuit tuned to adjust a harmonic distortion; and the second inductive element, the second capacitive element, and the fourth inductive element form a second resonant circuit tuned to adjust the harmonic distortion.

Aspect 18: The RF transceiver according to any of Aspects 12–17, wherein the amplifier further comprises: a first capacitive element coupled between a third terminal of the first inductive element and a reference potential node; and a second capacitive element coupled between a fourth terminal of the second inductive element and the reference potential node, wherein: the first inductive element and the first capacitive element form a first resonant circuit tuned to adjust a harmonic distortion; and the second inductive element and the second capacitive element form a second resonant circuit tuned to adjust the harmonic distortion.

Aspect 19: The RF transceiver of Aspect 17 or 18, wherein the amplifier further comprises: a first node coupled between the third terminal of the first inductive element and the first capacitive element; a second node coupled between the fourth terminal of the second inductive element and the second capacitive element; and a switch coupled between the first node and the second node, wherein the switch is configured to selectively bypass or enable the second transistor.

Aspect 20: The RF transceiver according to any of Aspects 12–19, wherein the amplifier further comprises a set of switches, wherein at least one switch of the set of switches is coupled in parallel with the second transistor and the fourth transistor, wherein the set of switches is configured to switch among at least a first mode and a second mode, wherein the first mode is configured to bypass a set of transistors in the first transistor stack and the second transistor stack, and wherein the amplifier is configured to operate with a first supply voltage and a first output power while the set of switches is switched in the first mode.

Aspect 21: The RF transceiver of Aspect 20, wherein the second mode is configured to enable the set of transistors in the first transistor stack and the second transistor stack, wherein the amplifier is configured to operate with a second supply voltage and a second output power while the set of switches is switched in the second mode, wherein the second supply voltage is higher than the first supply voltage, and the second output power is higher than the first output power.

Aspect 22: The RF transceiver according to any of Aspects 12–21, wherein: the first input node is coupled to a gate of the first transistor; the second input node is coupled to a gate of the second transistor; the amplifier further comprises a first output node and a second output node, wherein the first output node and the second output node form a differential output pair for a differential output signal; the first output node is coupled to a first drain of the first transistor stack; and the second output node is coupled to a second drain of the second transistor stack.

Aspect 23: A method of operating an amplifier, comprising: outputting a first control signal that triggers a first set of switches to switch from a first mode to a second mode; and amplifying a first differential input signal, via an amplifier, while the first set of switches is in the second mode, wherein the amplifier comprises: a first transistor stack comprising a first input node, a first transistor, and a second transistor; a second transistor stack comprising a second input node, a third transistor, and a fourth transistor, wherein the first input node and the second input node form an input pair for the first differential input signal; a first inductive element having a first terminal coupled between the first transistor and the second transistor; and a second inductive element having a second terminal coupled to a drain of the second transistor, wherein the first inductive element is arranged to be inductively coupled to the second inductive element.

Aspect 24: The method of Aspect 23, wherein amplifying the first differential input signal comprises: bypassing a first set of transistors in the first transistor stack and the second transistor stack; and operating the amplifier with a first supply voltage and a first output power while the first set of switches is switched in the second mode.

Aspect 25: The method of Aspect 24, further comprising: outputting a second control signaling that triggers the first set of switches to switch from the second mode to the first mode; and amplifying a second differential input signal, via the amplifier, while the first set of switches is in the first mode.

Aspect 26: The method of Aspect 25, wherein amplifying the second differential input signal comprises: enabling the first set of transistors in the first transistor stack and the second transistor stack; and operating the amplifier with a second supply voltage and a second output power while the first set of switches is switched in the first mode.

Aspect 27: The method of Aspect 26, wherein the second supply voltage is higher than the first supply voltage, and the second output power is higher than the first output power.

Aspect 24: An apparatus configured to perform a method in accordance with any of Aspects 23–27.

Aspect 25: An apparatus comprising means for performing a method in accordance with any of Aspects 23–27.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general-purpose processor, a digital signal processor (DSP), an artificial intelligence (AI) processor, an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, identifying, mapping, applying, choosing, establishing, and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” The use of a definite article (e.g., “the” or “said”) before an element is not intended to impart a singular meaning (e.g., “one and only one”) on an otherwise plural meaning (e.g., “one or more”) associated with the element unless specifically so stated. Unless specifically stated otherwise, the term “some” refers to one or more. The terms “set” and “group” are intended to include one or more elements, and may be used interchangeably with “one or more.” No claim element is to be construed under the provisions of 35 U.S.C. § 112(f) unless the element is expressly recited using the phrase “means for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. An amplifier, comprising:
a first transistor stack comprising a first input node, a first transistor, and a second transistor;
a second transistor stack comprising a second input node, a third transistor, and a fourth transistor, wherein the first input node and the second input node form an input pair for a differential input signal;
a first inductive element having a first terminal coupled between the first transistor and the second transistor; and
a second inductive element having a second terminal coupled to a drain of the second transistor, wherein the first inductive element is arranged to be inductively coupled to the second inductive element.

2. The amplifier of claim 1, further comprising:
a third inductive element having a third terminal coupled between the third transistor and the fourth transistor; and
a fourth inductive element having a fourth terminal coupled to a drain of the fourth transistor, wherein the third inductive element is arranged to be inductively coupled to the fourth inductive element.

3. The amplifier of claim 2, wherein:
the first transistor stack further comprises a fifth transistor;
the second transistor stack further comprises a sixth transistor;
the second terminal of the second inductive element is coupled between the second transistor and the fifth transistor; and
the fourth terminal of the fourth inductive element is coupled between the fourth transistor and the sixth transistor.

4. The amplifier of claim 3, further comprising a fifth inductive element having a fifth terminal coupled to a drain of the fifth transistor, wherein the fifth inductive element is arranged to be inductively coupled to the third inductive element and the first inductive element.

5. The amplifier of claim 4, further comprising a sixth inductive element having a sixth terminal coupled to a drain of the sixth transistor, wherein the sixth inductive element is arranged to be inductively coupled to the third inductive element and the fourth inductive element.

6. The amplifier of claim 2, further comprising:
a first capacitive element coupled between a fifth terminal of the first inductive element and a reference potential node and between a sixth terminal of the third inductive element and the reference potential node; and
a second capacitive element coupled between a seventh terminal of the second inductive element and the reference potential node and between a eighth terminal of the fourth inductive element, wherein:
the first inductive element, the first capacitive element, and the third inductive element form a first resonant circuit tuned to adjust a harmonic distortion; and
the second inductive element, the second capacitive element, and the fourth inductive element form a second resonant circuit tuned to adjust the harmonic distortion.

7. The amplifier of claim 6, further comprising:
a first node coupled between the third terminal of the first inductive element and the first capacitive element;
a second node coupled between the fourth terminal of the second inductive element and the second capacitive element; and
a switch coupled between the first node and the second node, wherein the switch is configured to selectively bypass or enable the second transistor.

8. The amplifier of claim 1, further comprising a set of switches, wherein at least one switch of the set of switches is coupled in parallel with the second transistor and the fourth transistor, wherein the set of switches is configured to switch among at least a first mode and a second mode, wherein the first mode is configured to bypass a set of transistors in the first transistor stack and the second transistor stack, and wherein the amplifier is configured to operate with a first supply voltage and a first output power while the set of switches is switched in the first mode.

9. The amplifier of claim 8, wherein the second mode is configured to enable the set of transistors in the first transistor stack and the second transistor stack, wherein the amplifier is configured to operate with a second supply voltage and a second output power while the set of switches is switched in the second mode, wherein the second supply voltage is higher than the first supply voltage, and the second output power is higher than the first output power.

10. The amplifier of claim 1, wherein:
the first input node is coupled to a gate of the first transistor;
the second input node is coupled to a gate of the second transistor;
the amplifier further comprises a first output node and a second output node, wherein the first output node and the second output node form a differential output pair for a differential output signal;
the first output node is coupled to a first drain of the first transistor stack; and
the second output node is coupled to a second drain of the second transistor stack.

11. A radio frequency (RF) transceiver, comprising:
a transmit chain comprising an amplifier, wherein the amplifier comprises:
a first transistor stack comprising a first input node, a first transistor, and a second transistor;
a second transistor stack comprising a second input node, a third transistor, and a fourth transistor, wherein the first input node and the second input node form an input pair for a differential input signal;
a first inductive element having a first terminal coupled between the first transistor and the second transistor; and
a second inductive element having a second terminal coupled to a drain of the second transistor, wherein the first inductive element is arranged to be inductively coupled to the second inductive element;
one or more memories; and
one or more processors coupled to the one or more memories and the transmit chain, the one or more processors being configured to provide a signal to the transmit chain for transmission.

12. The RF transceiver of claim 11, wherein the amplifier further comprises:
a third inductive element having a third terminal coupled between the third transistor and the fourth transistor; and
a fourth inductive element having a fourth terminal coupled to a drain of the fourth transistor, wherein the third inductive element is arranged to be inductively coupled to the fourth inductive element.

13. The RF transceiver of claim 12, wherein:
the first transistor stack further comprises a fifth transistor;
the second transistor stack further comprises a sixth transistor;
the second terminal of the second inductive element is coupled between the second transistor and the fifth transistor; and
the fourth terminal of the fourth inductive element is coupled between the fourth transistor and the sixth transistor.

14. The RF transceiver of claim 12, wherein the amplifier further comprises:
a first capacitive element coupled between a fifth terminal of the first inductive element and a reference potential node and between a sixth terminal of the third inductive element and the reference potential node; and
a second capacitive element coupled between a seventh terminal of the second inductive element and the reference potential node and between a eighth terminal of the fourth inductive element, wherein:
the first inductive element, the first capacitive element, and the third inductive element form a first resonant circuit tuned to adjust a harmonic distortion; and
the second inductive element, the second capacitive element, and the fourth inductive element form a second resonant circuit tuned to adjust the harmonic distortion.

15. The RF transceiver of claim 14, wherein the amplifier further comprises:
a first node coupled between the third terminal of the first inductive element and the first capacitive element;
a second node coupled between the fourth terminal of the second inductive element and the second capacitive element; and
a switch coupled between the first node and the second node, wherein the switch is configured to selectively bypass or enable the second transistor.

16. A method of operating an amplifier, comprising:
outputting a first control signal that triggers a first set of switches to switch from a first mode to a second mode; and
amplifying a first differential input signal, via an amplifier, while the first set of switches is in the second mode, wherein the amplifier comprises:
a first transistor stack comprising a first input node, a first transistor, and a second transistor;
a second transistor stack comprising a second input node, a third transistor, and a fourth transistor, wherein the first input node and the second input node form an input pair for the first differential input signal;
a first inductive element having a first terminal coupled between the first transistor and the second transistor; and
a second inductive element having a second terminal coupled to a drain of the second transistor, wherein the first inductive element is arranged to be inductively coupled to the second inductive element.

17. The method of claim 16, wherein amplifying the first differential input signal comprises:
bypassing a first set of transistors in the first transistor stack and the second transistor stack; and
operating the amplifier with a first supply voltage and a first output power while the first set of switches is switched in the second mode.

18. The method of claim 17, further comprising:
outputting a second control signaling that triggers the first set of switches to switch from the second mode to the first mode; and
amplifying a second differential input signal, via the amplifier, while the first set of switches is in the first mode.

19. The method of claim 18, wherein amplifying the second differential input signal comprises:
enabling the first set of transistors in the first transistor stack and the second transistor stack; and
operating the amplifier with a second supply voltage and a second output power while the first set of switches is switched in the first mode.

20. The method of claim 19, wherein the second supply voltage is higher than the first supply voltage, and the second output power is higher than the first output power.
